(19) United States
(12) Patent Application Publication
(10) Pub. No.: US 2025/0328165 A1
(43) Pub. Date: Oct. 23, 2025

(54) DOCKABLE MULTI-PURPOSE ELECTRONIC TABLET SYSTEM

(71) Applicant: Google LLC, Mountain View, CA (US)

(72) Inventors: Wenson Chern, San Jose, CA (US); Vivek Saini, Sunnyvale, CA (US); Valentin Shaun de la Fuente, San Francisco, CA (US); Juan Manuel Fantin, Mountain View, CA (US); David F. Chang, Los Altos, CA (US); Prashant Bhogilal Patel, San Jose, CA (US); Bengt Gunnar Brummer, San Francisco, CA (US); Jason Stanley Pi, Fremont, CA (US); Amy Lai Wong, Newark, CA (US)

(73) Assignee: Google LLC, Mountain View, CA (US)

(21) Appl. No.: 18/863,558

(22) PCT Filed: May 10, 2023
(86) PCT No.: PCT/US2023/021644

§ 371 Date: Nov. 6, 2024

Related U.S. Application Data
(60) Provisional application No. 63/364,479, filed on May 10, 2022.

(51) Int. Cl. G06F 1/16; H04R 1/02; H05K 5/02

(52) U.S. Cl. CPC G06F 1/1632; G06F 1/1626; G06F 1/1635; G06F 1/166; H04R 1/028; H05K 5/0204

(57) ABSTRACT

The present document describes techniques for a dockable and undockable multiple-purpose electronic tablet device. These techniques enable a tablet device, to be docked to a dock, which secures the tablet device for use, for example, of a display screen of the tablet device and/or for use of a speaker of the dock. The tablet device is also electrically couplable to the dock to enable communication between the tablet device and the dock and to enable power transfer from the dock to the tablet device for charging a battery of the tablet device.

### CROSS-REFERENCE TO RELATED APPLICATION

This application claims the benefit of and priority to U.S. Provisional Application No. 63/364,479, filed on May 10, 2022, and titled “DOCKABLE AND UNDOCKABLE MULTI-PURPOSE ELECTRONIC TABLET DEVICE,” the content of which is herein incorporated by reference in its entirety for all purposes.

### BACKGROUND

Electronic tablet devices have become increasingly popular devices due to their larger display screens and touch-input capabilities. However, challenges arise when a user sets the tablet device on a surface but wishes to continue interacting with the device to consume media content. Due to their form factor, tablet devices are generally designed to lie on a flat surface, which enables the user to view the display by looking downward. If the user wishes to set the tablet device on the kitchen counter, for example, to view a recipe or watch a basketball game while preparing a meal, challenges arise in stabilizing the device in an upright position.

### SUMMARY

The present document describes techniques for a dockable and undockable multiple-purpose electronic tablet device. These techniques enable a tablet device, operable in tablet device mode, to be docked to a dock, which secures the tablet device in an upright position for substantial horizontal viewing of a display screen of the tablet device. The tablet device is also electrically couplable to the dock to enable communication between the tablet device and the dock and to enable power transfer from the dock to the tablet device for charging a battery of the tablet device.

In aspects, the tablet device includes electrical contacts (e.g., pogo pads) on a rear surface, which is opposite a display screen of the tablet device. When docked to the dock, the electrical contacts electrically couple to corresponding receptacle contacts on the dock, forming a solid and physical connection that enables the transfer of electrical current and electrical signals. The electrical contacts may be positioned at any suitable location on the rear surface, which enables the electrical contacts to couple to (e.g., mate with) the corresponding receptacle contacts on the dock.

The tablet device may be docked (e.g., mounted, coupled, secured) to the dock via a coupling mechanism, which may include a magnetic coupling mechanism or a mechanical coupling mechanism. For example, magnets may be implemented in the dock and/or the tablet device to generate a magnetic attraction force that securely connects and holds the tablet device to the dock. With sufficient counter force (e.g., pull) applied by a user, the tablet device can decouple from the dock.

The tablet device and the dock together form a modular system. In one example, the dock may include an audio output device (e.g., speaker) to provide audio output from the tablet device. Digital signals may be communicated from the tablet device to the dock, via the electrical contacts and the corresponding receptacle contacts, and the dock may correspondingly output audio signals via the audio output device. In this way, the tablet device and the dock can communicate via a physical connection rather than via wireless communication (e.g., Bluetooth™). However, in some implementations, the tablet device may communicate with the dock via a wireless communication.

This summary is provided to introduce simplified concepts of a dockable and undockable multiple-purpose electronic tablet device, which is further described below in the Detailed Description. This summary is not intended to identify essential features of the claimed subject matter, nor is it intended for use in determining the scope of the claimed subject matter.

### BRIEF DESCRIPTION OF DRAWINGS

The details of one or more aspects of a dockable and undockable multiple-purpose electronic tablet device are described in this document with reference to the following drawings. The same numbers are used throughout the drawings to reference like features and components:

FIG. 1 illustrates a block diagram of an embodiment of a tablet dock system.

FIG. 2 illustrates an embodiment of a device that can be docked with a docking station or “dock” using magnets, according to some implementations of the present disclosure.

FIG. 3 illustrates a schematic front view of a dock, according to some implementations of the present disclosure.

FIG. 4 illustrates a schematic side view of an embodiment of a dock, according to some implementations of the present disclosure.

FIG. 5 illustrates a schematic front view of an embodiment of a tablet computer magnetically docked, according to some implementations of the present disclosure.

FIG. 6 illustrates a schematic rear view of an embodiment of a tablet dock system having the tablet magnetically docked with the dock, according to some implementations of the present disclosure.

FIG. 7 illustrates a schematic side view of an embodiment of a tablet computer docked with a dock, according to some implementations of the present disclosure.

FIG. 8 illustrates a flowchart of a method of operating a tablet dock system having the tablet magnetically docked with the dock, according to some implementations of the present disclosure.

FIG. 9 illustrates a schematic plan view and schematic cross-section views of a foot of a dock, according to some implementations of the present disclosure.

FIG. 10 illustrates a schematic plan view and schematic cross-section views of a foot of a dock, according to some implementations of the present disclosure.

FIG. 11 illustrates a schematic plan view and schematic cross-section views of a foot of a dock, according to some implementations of the present disclosure.

FIG. 12 illustrates a flowchart of a method of operating a dock, according to some implementations of the present disclosure.

FIG. 13 illustrates a schematic dock, according to some implementations of the present disclosure.

FIG. 14 illustrates an embodiment of a device that can be docked with a dock, according to some implementations of the present disclosure.

FIG. 15 illustrates a flowchart of a method of operating a tablet dock system having the tablet magnetically docked with the dock, according to some implementations of the present disclosure.

### DETAILED DESCRIPTION

The present document describes a dockable and undockable multiple-purpose electronic device, such as a tablet computer or a tablet device. The aspects described herein include an electronic device (e.g., tablet device) that can, when undocked, operate as a standalone computing device when undocked and when docked to a dock, receive power from the dock and communicate with the dock.

The tablet device may be docked while oriented in a landscape orientation. When undocked, the tablet may be operated in a landscape or portrait orientation. The tablet device and the dock may be configured to wirelessly communicate. The tablet device includes electrical contacts (e.g., pogo pads) that are exposed to the environment and configured to physically connect with corresponding electrical contacts on the dock. Such a physical connection enables the tablet device to communicate with the dock without wirelessly communicating with the dock, and enables the tablet device to receive power from the dock. As an example, while power is received by the tablet device from the dock, the tablet can output an audio signal to the dock that is used to generate sound via one or more speakers of the dock.

While features and concepts of the described dockable and undockable multiple-purpose electronic tablet device can be implemented in any number of different environments, aspects are described in the context of the following examples.

In some embodiments, the dock includes a speaker, and the dock and the tablet device form an acoustic environment forward of the speaker, where the acoustic environment is configured to properly transmit sound from the speaker, for example, without significant attenuation or distortion.

In some embodiments, the dock may include one or more abrasion feet, which significantly reduce slidable movement on a surface, particularly when the tablet device is docked to the dock in an upright position, the system experiences vibrations, for example caused by use of the speaker to generate audio signals.

In some embodiments, either or both of the dock and the tablet device includes one or more sensors configured to generate signals which may be used to determine whether the tablet device is properly aligned on the dock. In response to determining that the tablet device is properly aligned on the dock, the dock may provide power to the tablet device with one or more electrical contacts, and the dock may communicate with the device using one or more electrical contacts.

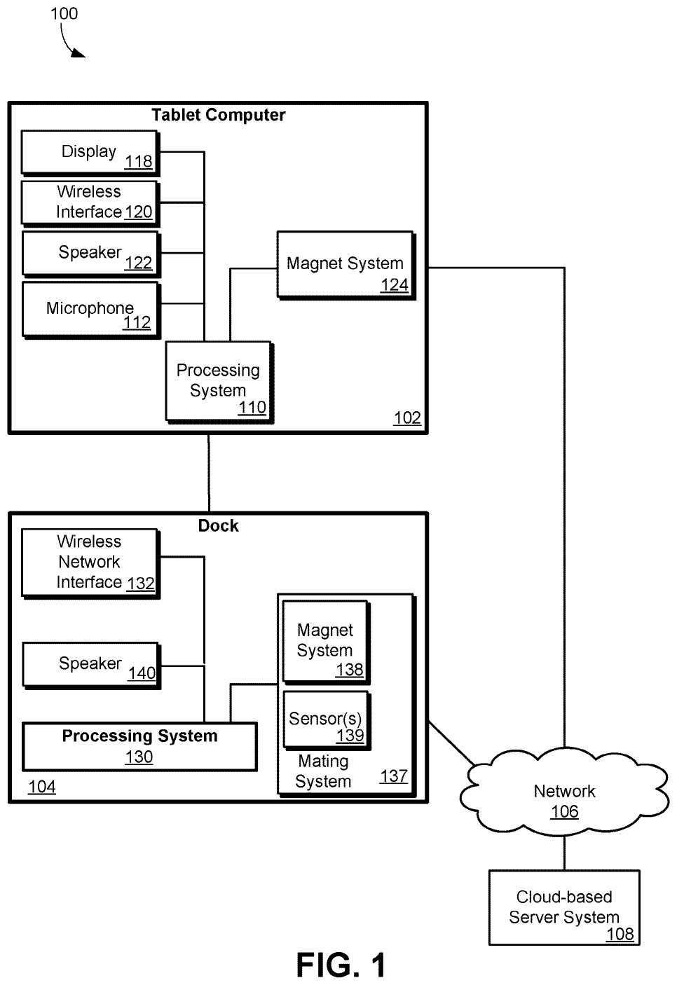

FIG. 1 illustrates a block diagram of an embodiment of an electronic device dock system 100. System 100 can include a computing device, such as tablet computer 102, a dock 104, a network 106; and cloud-based server system 108. The tablet computer 102 can include: processing system 110; one or more microphones 112; an electronic display 118; and a wireless interface 120. Processing system 110 may include one or more processors, which can include special-purpose or general-purpose processors that execute instructions stored using one or more non-transitory processor readable mediums. Processing system 110 can include one or more processors that are designed to execute machine learning (ML) models. Such processors, while able to analyze whether speech is or is not present, may or may not be able to analyze the content of such speech, such as to detect a trigger word or trigger phrase. Therefore, unless the trigger word or phrase is spoken, privacy of the content of the speech may be maintained. Syntiant® Neural Decision Processors™ represent one family of commercial processors that can execute a machine learning model that is trained to analyze speech for the presence of a keyword or phrase but otherwise ignore the content of such speech. When the keyword or phrase is detected, additional processing can be performed on the speech, either locally or remotely, such as to determine a command or action desired by the user who spoke the keyword or phrase.

Microphones 112 are configured to receive audio input from a user of the tablet computer 102. One or more microphones 112 may be in communication with processing system 110. If multiple microphones 112 are present, based upon the difference in time of arrival of sound at the multiple microphones, a direction from which a sound, such as speech, originated may be determined in relation to a SIM device. One or more microphones 112 may be in direct communication with only processing system 110 via a direct connection. Specifically, one or more microphones 112 can be electrically connected to only a processing system that executes a machine learning model that determines (e.g., a binary determination of whether or not speech is determined to be present) or scores (e.g., indicates a likelihood of speech being present) if speech is or is not present. The processing system may not have the capability to analyze the content of the speech. In various embodiments, the tablet computer 102 may include a speaker 122 of a type known in the art to output audio feedback to commands.

Magnet system 124 may include one or more magnets arranged to magnetically couple with corresponding one or more magnets of magnet system 138 of the dock. Magnet system 124 and magnet system 138 may be used to align the tablet computer 102 with the dock 104 during docking. Magnet system 124 (and/or magnet system 138) may include one or more electronically controllable magnets, one or more permanent magnets, one or more not electronically controllable magnets, one or more magnet modules, or a combination thereof.

In some embodiments, magnet system 124 (and/or magnet system 138) may include one or more magnetic field sensors, such as one or more magnetic field sensors, one or more magnetometers, one or more Hall effect sensors, and/or one or more other types of sensors configured to sense the presence of a magnet or a magnetic field. The magnetic field sensors may be configured to generate a signal indicative of proximity to a magnet.

Wireless interface 120 is in communication with processing system 110 and allows for communication with various wireless networks and/or wireless devices using one or more communication protocols. Wireless interface 120 may allow for communication with a Wi-Fi based wireless local area network. Wireless interface 120 can allow for communication directly with other devices, such as via Bluetooth, Bluetooth Low Energy (BLE), or some other low-power device-to-device communication protocol. In some embodiments, wireless interface 120 allows for communication with a wearer's smartphone, thus allowing information collected using the tablet computer 102 to be analyzed by and presented using the wearer's smartphone. In some embodiments, wireless interface 120 allows for communication with wireless network interface 132 of dock 104.

In some embodiments, electronic display 118 may be present. In various aspects, the electronic display 118 may display any visual information associated with any applications running on the tablet computer 102. Electronic display 118 can allow for information determined based on data collected from the various sensors of the tablet computer 102 to be directly presented to a user. For example, the electronic display 118 may display information, interfaces, and/or commands associated with smart home devices, social media applications, internet searches, weather applications, news applications, etc. For instance, electronic display 118 may allow a user to control various smart home devices located throughout a home.

The tablet computer 102 may be or may be used with a smartphone, a smartwatch, laptop, gaming device, or a smart home hub device that is used to interact with various smart home devices present within a home. The dock 104 may be part of a smart home assistant device system. (Generally, the dock 104 can include a housing (e.g., a dock housing) that houses some or all of the components of the dock 104.

The dock 104 can include a processing system 130. Processing system 130 can include one or more processors configured to perform various functions. Processing system 130 can include one or more special-purpose or general-purpose processors. Such special-purpose processors may include processors that are specifically designed to perform the functions detailed herein. Such special-purpose processors may be ASICs or FPGAs which are general-purpose components that are physically and electrically configured to perform the functions detailed herein. Such general-purpose processors may execute special-purpose software that is stored using one or more non-transitory processor-readable mediums, such as random access memory (RAM), flash memory, a hard disk drive (HDD), or a solid state drive (SSD).

Dock 104 may include a mating system 137, embodiments of which are described in more detail elsewhere herein. The dock 104 may include a speaker 140 (which can represent an embodiment of speaker 122) to output audio, such as music and/or feedback to commands, and wireless network interface 132, which can represent an embodiment of wireless interface 120.

Mating system 137 can include magnet system 138, and one or more magnetic field sensors 139. Magnet system 138 may include one or more magnets arranged to magnetically couple with corresponding one or more magnets of magnet system 124 of the tablet computer 102. Magnet system 124 and magnet system 138 may be used to align the tablet computer 102 with the dock 104 during docking. Magnet system 138 (and/or magnet system 124) may include one or more electronically controllable magnets (e.g., electropermanent magnets), one or more permanent magnets, one or more not electronically controllable magnets, one or more magnet modules, or a combination thereof.

Magnetic field sensors 139, may include, for example, one or more magnetic field sensors, one or more Hall effect sensors, and/or one or more other types of sensors configured to sense the presence (and, possibly, magnitude) of a magnetic field. The magnetic field sensors may be configured to generate a signal indicative of proximity to a magnet.

Processing system 130 may be configured to receive a signal that can be analyzed to determine whether the tablet computer 102 is properly docked with the dock 104. The signal may be transmitted, for example, by, for example, either or both of magnet system 124 and magnetic field sensors 139. In response to receiving the signal, processing system 130 may be configured to provide power and/or communication signals to the tablet computer 102 through the electrical contacts of the dock 104.

In various embodiments, other sensors or components (not shown) may be located on the dock 104. For example, one or more environmental sensors may be incorporated into the dock 104 and can include a light sensor, a microphone for receiving audio input from a user, a temperature sensor, etc. In some embodiments, multiple instances of some or all of these sensors may be present. A camera and/or humidity sensor may be incorporated into the dock 104 and/or the tablet computer 102. As another example, active infrared sensors may be included. In some embodiments, some data, such as humidity data, may be obtained from a nearby weather station that has data available via the Internet. In some embodiments, active acoustic sensing methods, including, but not limited to, sonar and ultrasound, and including either single or arrayed acoustic sources and/or receivers may be implemented. Such arrangements may be used as one or more adjunct sensing modalities incorporated with the other sensors and methods described herein.

Tablet computer 102 may include various interfaces. Display 118, which may be a touchscreen, can allow processing system 110 to present information for viewing by one or more users and can receive user input that is provided as an input to processing system 110. A wireless network interface can allow for communication using a wireless local area network (WLAN), such as a WiFi-based network. Other network-based and direct wireless communication protocols are possible, such as Bluetooth family protocols, WiFi Direct, etc. Speaker 122 can allow for sound, such as synthesized speech, to be output. For instance, responses to spoken commands received via microphone 112 may be output via speaker 122 and/or display 118. The spoken commands may be analyzed locally by the tablet computer 102 or may be transmitted via a wireless network interface to cloud-based server system 108 for analysis. A response, based on the analysis of the spoken command, can be sent back to the tablet computer via the wireless network interface for output via speaker 122 and/or display 118. Additionally, or alternatively, the speaker 122 and microphone 112 may be collectively configured for active acoustic sensing, including ultrasonic acoustic sensing. Additionally, or alternatively, other forms of wireless communication may be possible, such as using a low-power wireless mesh network radio and protocol (e.g., Thread) to communicate with various smart home devices. In some embodiments, a wired network interface, such as an Ethernet connection, may be used for communication with a network. Further, the evolution of wireless communication to fifth generation (5G) and sixth generation (6G) standards and technologies provides greater throughput with lower latency which enhances mobile broadband services. 5G and 6G technologies also provide new classes of services, over control and data channels, for vehicular networking (V2X), fixed wireless broadband, and the Internet of Things (IoT). Such standards and technologies may be used for communication by the tablet computer 102.

The low-power wireless mesh network radio and protocol may be used for communicating with power limited devices. A power-limited device may be an exclusively battery powered device. Such devices may rely exclusively on one or more batteries for power and therefore, the amount of power used for communications may be kept low in order to decrease the frequency at which the one or more batteries need to be replaced. In some embodiments, a power-limited device may have the ability to communicate via a relatively high-power network (e.g., WiFi) and the low-power mesh network. The power-limited device may infrequently use the relatively high-power network to conserve power. Examples of such power-limited devices include environmental sensors (e.g., temperature sensors, carbon monoxide sensors, smoke sensors, motion sensors, presence detectors) and other forms of remote sensors.

Some embodiments of the tablet computer 102 do not have any still camera or video camera. By not incorporating an on-board camera, users nearby may be reassured about their privacy. For example, the tablet computer 102 can typically be installed in a user's bedroom. For many reasons, a user would not want a camera located in such a private space or aimed toward the user while the user is sleeping. In other embodiments, the tablet computer 102 may have a camera. In some of these embodiments, the camera's lens may be obscured by a mechanical lens shutter. In order to use the camera, the user may be required to physically open the shutter to allow the camera to have a view of the environment of the tablet computer 102. The user can be assured of privacy from the camera when the shutter is closed.

Wireless network interface can allow for wireless communication with network 106. Network 106 can include one or more public and/or private networks. Network 106 can include a local wired or wireless network that is private, such as a home wireless LAN. Network 106 may also include a public network, such as the Internet. Network 106 can allow for the tablet computer 102 to communicate with remotely located cloud-based server system 108.

Cloud-based server system 108 may additionally or alternatively provide other cloud-based services. For instance, the tablet computer 102 may additionally function as a home assistant device. A home assistant device may respond to vocal queries from a user. In response to detecting a vocal trigger phrase being spoken, the tablet computer 102 may record audio. A stream of the audio may be transmitted to cloud-based server system 108 for analysis. Cloud-based server system 108 may perform a speech recognition process, use a natural language processing engine to understand the query from the user, and provide a response to be output by the tablet computer 102 as synthesized speech, an output to be presented on display 118, and/or a command to be executed by the tablet computer 102 (e.g., raise the volume of the tablet computer 102) or sent to some other smart home device. Further, queries or commands may be submitted to cloud-based server system 108 via display 118, which may be a touchscreen. For instance, the tablet computer 102 may be used to control various smart home devices or home automation devices. Such commands may be sent directly by the tablet computer 102 to the device to be controlled or may be sent via cloud-based server system 108.

In some embodiments, the tablet computer 102 being docked to dock 104 results in a portion of the tablet computer 102 occluding a portion of the speaker 122 of dock 104. Despite the occlusion, the acoustic environment formed by the dock 104 and the tablet computer 102 properly transmits sound from the speaker 122, for example, without significant attenuation or distortion.

In some embodiments, the dock 104 may include one or more abrasion feet, which significantly reduce sliding movement on a surface on which the dock 104 is placed. For example, when the tablet computer 102 is docked to the dock 104 in an upright position, the system experiences vibrations, for example caused by use of the speaker 122 to generate audio signals. The one or more abrasion feet of the dock 104 may be shaped so as to generate sufficient friction with the surface that the likelihood of sliding movement is minimal or prevented.

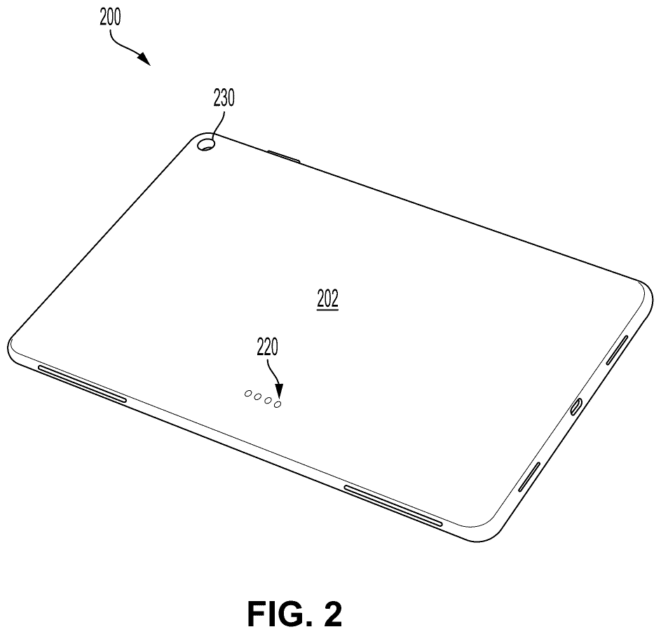

FIG. 2 illustrates an embodiment of an electronic device 200 that is configured to dock with a dock using magnets and, in some embodiments, electrical contacts. The electronic device 200 can be a tablet computer, such as tablet computer 102, or, more specifically, a tablet computer that serves as a home assistant device or hub as previously detailed. One or more magnets may be hidden within the electronic device 200 behind rear face 202. Device 200 includes multiple conductive electrical contacts 220 (e.g., metallic pads) that are used to transfer data with and/or obtain power from a dock when the electronic device 200 is in a docked position. As illustrated, four electrical contacts 220 are present. In other embodiments, a greater or fewer number of electrical contacts 220 may be present. The arrangement of electrical contacts 220 can also vary by embodiment. In some embodiments, the electrical contacts comprise, for example, one or more contact pads, one or more pins, or a combination of pads and pins. Other components, such as camera 230, may be present on or accessible through rear face 202.

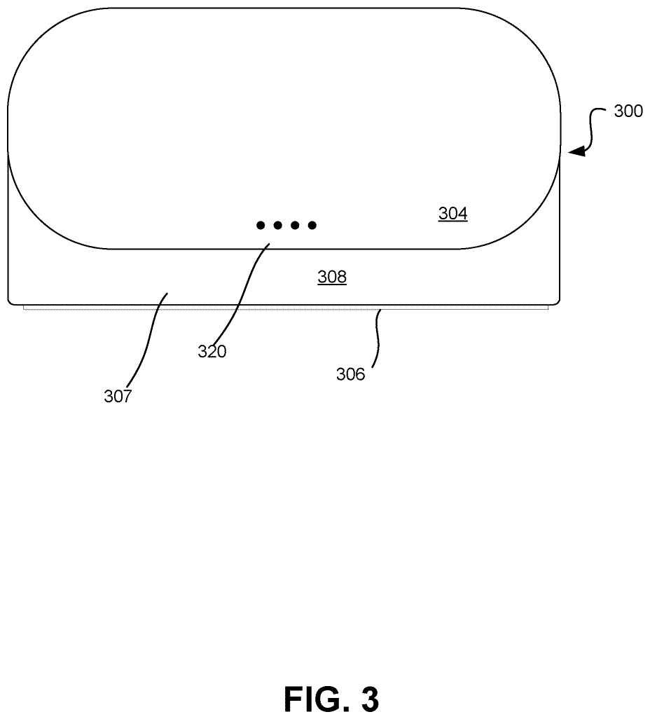

FIG. 3 illustrates a schematic front view of a dock 300, according to some embodiments. Dock 300 may include a mating system, such as that described in more detail elsewhere herein. For example, dock 300 may have features similar or identical to those of dock 104 described above.

The mating system of dock 300 may include a magnet system and one or more magnetic field sensors. The magnet system may include one or more magnets arranged to align with and magnetically couple with corresponding one or more magnets of a magnet system of an electronic device docked with dock 300 such that a mating face of the electronic device is held against mating face 304 of dock 300 by the magnetic fields of the magnet system of dock 300 and the magnet system of the electronic device.

The magnetic field sensors of dock 300 may include, for example, one or more magnetic field sensors, one or more magnetometers, one or more Hall effect sensors, and/or one or more other types of sensors configured to sense the presence of a magnet or a magnetic field. The magnetic field sensors may be configured to generate a signal indicative of a magnitude of a magnetic field, which can indicate proximity to one or more magnets.

Dock 300 may include a processing system configured to receive a signal indicating whether the electronic device is properly docked with the dock 300. The signal may be initiated, for example, by, for example, either or both of the magnetic field sensors of dock 300 and magnetic field sensors of the electronic device. In response to receiving the signal, the processing system may be configured to provide power and/or communication signals to the electronic device through the electrical contacts 320 of the dock 300.

In some embodiments, the dock 300 may include an internal speaker directed toward speaker face 308. Dock 300 may be configured to cause the internal speaker to generate sound according to, for example, data from an audio file, or according to, for example, signals from a microphone system.

In some embodiments, the dock 300 may include a stability foot 306, which significantly reduces sliding movement on a surface on which the dock 300 is placed. For example, the dock 300 may experience vibrations, for example caused by use of the speaker of dock 300. The stability foot 306 of the dock 300 may be shaped so as to generate sufficient friction with the surface that the sliding movement is minimal or is prevented.

Foot 306 may comprise an elastomeric material. For example, in some embodiments, foot 306 includes silicon. In addition, foot 306 may be attached to a surface of the housing 307 of dock 300 using an adhesive. In some embodiments, foot 306 is attached to the surface of the housing 307 by topological features of foot 306 which protrude through holes in the surface of the housing 307. In some embodiments, foot 306 is attached to the surface of the housing 307 using another mechanism, such as a fastener.

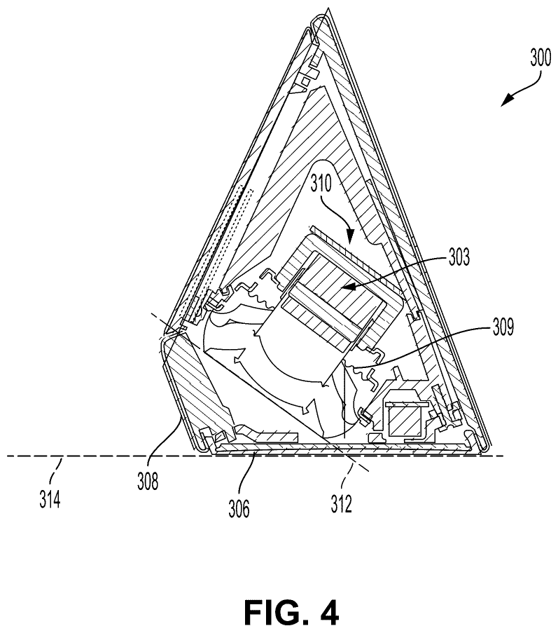

FIG. 4 illustrates a schematic side view of dock 300, according to some implementations of the present disclosure. As illustrated, mating face 304, speaker face 308, and foot 306 of dock 300 are indicated. In addition, speaker 310 having indicated speaker components 303 (a magnetic post) and 309 (a spider), and a mechanical orientation and connection arrangement are also illustrated.

In addition, FIG. 4 identifies speaker plane 312. The speaker plane 312 is defined by a speaker, which faces a direction perpendicular to the speaker plane 312. In some embodiments, the speaker includes a diaphragm which defines the speaker plane 312. For example, the diaphragm may have a substantially planar portion which moves to cause sound waves in response to an audio signal provided to the speaker, where the planar portion of the diaphragm defines the speaker plane 312. Alternatively, the speaker plane may be defined by a surround of the speaker. As illustrated, the internal speaker plane 312 of dock 300 outwardly faces speaker face 308.

FIG. 4 also identifies a foot plane 314 defined by foot 306. For example, when dock 300 is positioned on a surface, the portions of foot 306 contacting the surface may define foot plane 314. In some embodiments, the speaker plane 312 and the foot plane 314 intersect with an angle between any of: 45 and 55 degrees, between 55 and 65 degrees, between 65 degrees and 75 degrees, between 75 degrees and 85 degrees, between 85 degrees and 95 degrees, between 44 degrees and 48 degrees, between 47 degrees and 51 degrees, between 49 degrees and 53 degrees, between 52 degrees and 56 degrees, between 54 degrees and 58 degrees, between 57 degrees and 61 degrees, between 59 degrees and 63 degrees, between 62 degrees and 66 degrees, between 64 degrees and 68 degrees, between 67 degrees and 71 degrees, between 69 degrees and 73 degrees, between 72 degrees and 76 degrees, between 74 degrees and 78 degrees, between 77 degrees and 81 degrees, between 79 degrees and 73 degrees, between 72 degrees and 86 degrees, between 74 degrees and 78 degrees, between 77 degrees and 81 degrees, between 79 degrees and 83 degrees, between 82 degrees and 86 degrees, between 84 degrees and 88 degrees, between 87 degrees and 91 degrees, between 89 degrees and 93 degrees, and between 92 degrees and 96 degrees.

In some embodiments, the speaker plane 312 and the foot plane 314 intersect with an angle less than any of: 90 degrees, 85 degrees, 80 degrees, 75 degrees, 65 degrees, 60 degrees, 55 degrees, 50 degrees, 48 degrees, 45 degrees, 43 degrees, 40 degrees, 38 degrees, 35 degrees, 33 degrees, 30 degrees, 28 degrees, 25 degrees, 23 degrees. 20 degrees, 18 degrees, and 15 degrees.

In some embodiments, the speaker face 308 and the foot plane 314 intersect with an angle between any of: 45 and 55 degrees, between 55 and 65 degrees, between 65 degrees and 75 degrees, between 75 degrees and 85 degrees, between 85 degrees and 95 degrees, between 44 degrees and 48 degrees, between 47 degrees and 51 degrees, between 49 degrees and 53 degrees, between 52 degrees and 56 degrees, between 54 degrees and 58 degrees, between 57 degrees and 61 degrees, between 59 degrees and 63 degrees, between 62 degrees and 66 degrees, between 64 degrees and 68 degrees, between 67 degrees and 71 degrees, between 69 degrees and 73 degrees, between 72 degrees and 76 degrees, between 74 degrees and 78 degrees, between 77 degrees and 81 degrees, between 79 degrees and 73 degrees, between 72 degrees and 86 degrees, between 74 degrees and 78 degrees, between 77 degrees and 81 degrees, between 79 degrees and 83 degrees, between 82 degrees and 86 degrees, between 84 degrees and 88 degrees, between 87 degrees and 91 degrees, between 89 degrees and 93 degrees, and between 92 degrees and 96 degrees.

In some embodiments, the speaker face 308 and the foot plane 314 intersect with an angle less than any of: 90 degrees, 85 degrees, 80 degrees, 75 degrees, 65 degrees, 60 degrees, 55 degrees, 50 degrees, 48 degrees, 45 degrees, 43 degrees, 40 degrees, 38 degrees, 35 degrees, 33 degrees, 30 degrees, 28 degrees, 25 degrees, 23 degrees, 20 degrees, 18 degrees, and 15 degrees.

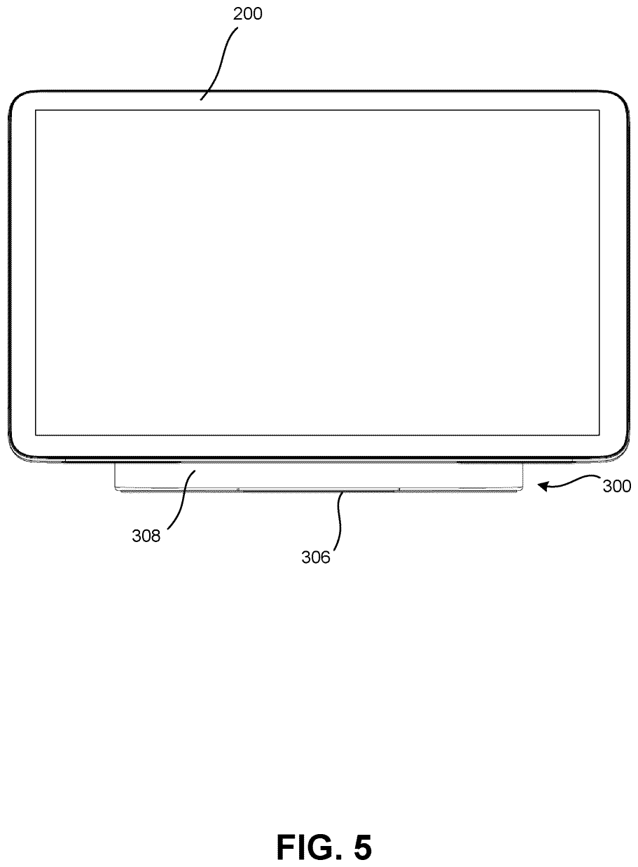

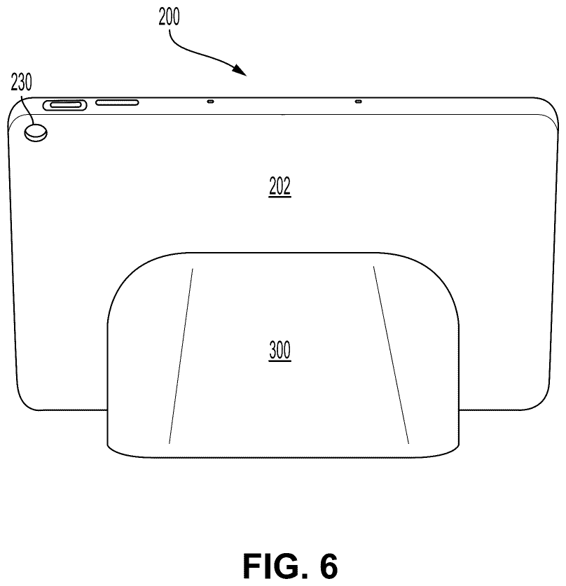

FIGS. 5 and 6 respectively illustrate a schematic front view and a schematic rear view of an embodiment of electronic device 200 docked with dock 300, according to some implementations of the present disclosure. In some embodiments, either or both of electronic device 200 and dock 300 include magnets or magnet systems, for example, similar or identical to those discussed elsewhere herein, which cause electronic device 200 to be held in place against dock 300, for example, such that mating face 202 of electronic device 200 is held in place against mating face 304 (not shown) of dock 300.

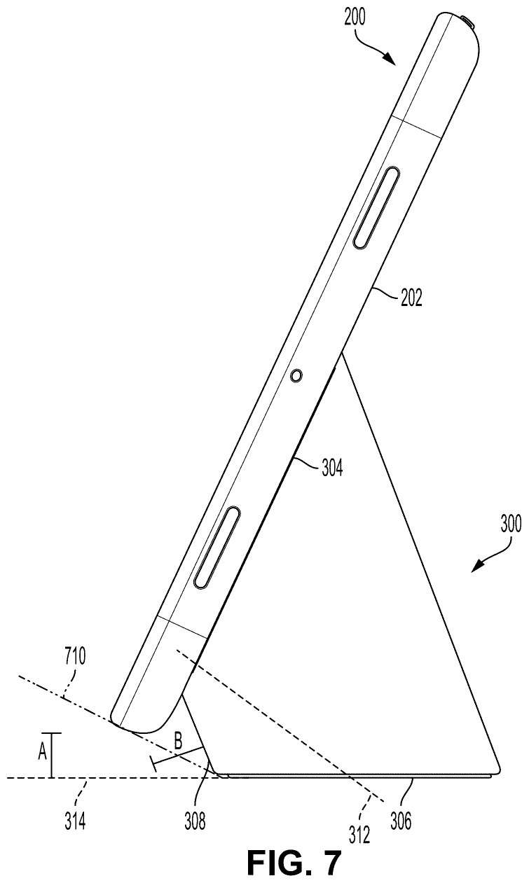

FIG. 7 illustrates a schematic side view of an embodiment of electronic device 200 docked with dock 300, according to some implementations of the present disclosure. Mating face 202 of electronic device 200 is magnetically held in place against mating face 304 of dock 300.

When electronic device 200 is docked with dock 300, a lowest point on electronic device 200 is spaced apart from a nearest point of foot plane 314 by a distance A. In some embodiments, distance A is less than any of: 30 mm, 28 mm, 25 mm, 23 mm, 20 mm, 18 mm, 16 mm, 15 mm, 14 mm, 13 mm, 12 mm, 11 mm, 10 mm, 9 mm, 8 mm, 7 mm, 6 mm, 5 mm, 4 mm, 3 mm, 2 mm, 1 mm. In some embodiments, the lowest point on electronic device 200 contacts or is below the foot plane. In some embodiments, distance A is any of: less than 30 mm and greater than 27 mm, less than 28 mm and greater than 25 mm, less than 25 mm and greater than 22 mm, less than 23 mm and greater than 21 mm, less than 20 mm and greater than 18 mm, less than 18 mm and greater than 16 mm, less than 16 mm and greater than 14 mm, less than 15 mm and greater than 13 mm, less than 14 mm and greater than 13 mm, less than 13 mm and greater than 12 mm, less than 12 mm and greater than 11 mm, less than 11 mm and greater than 10 mm, less than 10 mm and greater than 9 mm, less than 9 mm and greater than 8 mm, less than 8 mm and greater than 7 mm, less than 7 mm and greater than 6 mm, less than 6 mm and greater than 5 mm, less than 5 mm and greater than 4 mm, less than 4 mm and greater than 3 mm, less than 3 mm and greater than 2 mm, less than 2 mm and greater than 1 mm, less than 1 mm and greater than 0 mm. In some embodiments, the lowest point on electronic device 200 contacts or is below the foot plane.

When electronic device 200 is docked with dock 300, a lowest point on electronic device 200 is spaced apart from a nearest point of dock 300 by a distance B. In some embodiments, distance B is less than any of: 30 mm, 28 mm, 25 mm, 23 mm, 20 mm, 18 mm, 16 mm, 15 mm, 14 mm, 13 mm, 12 mm, 11 mm, 10 mm, 9 mm, 8 mm, 7 mm, 6 mm, and 5 mm. In some embodiments, distance B is any of: less than 30 mm and greater than 27 mm, less than 28 mm and greater than 25 mm, less than 25 mm and greater than 23 mm, less than 23 mm and greater than 21 mm, less than 20 mm and greater than 18 mm, less than 18 mm and greater than 16 mm, less than 16 mm and greater than 14 mm, less than 15 mm and greater than 13 mm, less than 14 mm and greater than 13 mm, less than 13 mm and greater than 12 mm, less than 12 mm and greater than 11 mm, less than 11 mm and greater than 10 mm, less than 10 mm and greater than 9 mm, less than 9 mm and greater than 8 mm, less than 8 mm and greater than 7 mm, less than 7 mm and greater than 6 mm, less than 6 mm and greater than 5 mm, and less than 5 mm and greater than 4 mm.

An occlusion plane 710 contacts a forward most portion of the housing of dock 300 at or near an intersection of a plane defined by speaker face 308 and foot plane 314, such that the speaker face 308 is occluded by electronic device 200 from some or all points of view which are both left of electronic device 200, according to the orientation of the figure, and higher than the occlusion plane 710, according to the orientation of the figure. In some embodiments, the occlusion plane contacts the electronic device and the dock such that the dock is occluded by electronic device from points of view which are between the occlusion plane and the electronic device on the device front face side of the electronic device. The occlusion plane 710 intersects the foot plane 314 with an angle which is less than any of: 60 degrees, 55 degrees, 50 degrees, 48 degrees, 45 degrees, 43 degrees, 40 degrees, 38 degrees, 35 degrees, 33 degrees, 30 degrees, 28 degrees, 25 degrees, 23 degrees, 20 degrees, 18 degrees, and 15 degrees. In some embodiments, the occlusion plane 710 intersects the foot plane 314 with an angle which is any of: less than 60 degrees and greater than 55 degrees, less than 55 degrees and greater than 50 degrees, less than 50 degrees and greater than 45 degrees, less than 48 degrees and greater than 43 degrees, less than 45 degrees and greater than 40 degrees, less than 43 degrees and greater than 38 degrees, less than 40 degrees and greater than 35 degrees, less than 38 degrees and greater than 33 degrees, less than 35 degrees and greater than 30 degrees, less than 33 degrees and greater than 30 degrees, less than 30 degrees and greater than 27 degrees, less than 28 degrees and greater than 25 degrees, less than 25 degrees and greater than 23 degrees, less than 23 degrees and greater than 21 degrees, less than 20 degrees and greater than 18 degrees, less than 18 degrees and greater than 16 degrees, and less than and 15 degrees and greater than 13 degrees.

Dock 300 may be configured to generate sound based on data of a test audio file while electronic device 200 is either docked therewith or not docked therewith. For example, while electronic device 200 is not docked with dock 300, dock 300 may use an internal speaker to generate sound having a reference power spectral characteristic, such that, as measured at a test distance D to the left of dock 300, according to the orientation of the figure and in the plane of the figure, an acoustic power may be measured for each of a plurality of frequency bins. For example, for each of 2048 adjacent frequency bins 16 Hz wide starting at 32 Hz, an acoustic power value may be measured. During the measurements, the electronic device 200 may be placed in a location so that the electronic device 200 does not influence the measurements. The test distance D may, for example, be less than any of: 10 cm, 15 cm, 20 cm, 25 cm, 30 cm, 35 cm, 40 cm, 50 cm, 60 cm, 75 cm, 90 cm, 100 cm, and another distance. In some embodiments, the test distance D may, for example, be any of: less than 10 cm and greater than 8 cm, less than 15 cm and greater than 12 cm, less than 20 cm and greater than 16 cm, less than 25 cm and greater than 20 cm, less than 30 cm and greater than 25 cm, less than 35 cm and greater than 30 cm, less than 40 cm and greater than 35 cm, less than 50 cm and greater than 45 cm, less than 60 cm and greater than 50 cm, less than 75 cm and greater than 60 cm, less than 90 cm and greater than 70 cm, and less than 100 cm and greater than 75 cm.

In some embodiments, while the electronic device 200 is docked with dock 300, dock 300 may use an internal speaker to generate sound having a test power spectral characteristic, such that, as measured at the same point that measurements were taken to characterize the reference power spectral characteristic, an acoustic power value may be measured for each of the plurality of frequency bins.

In some embodiments, each of the acoustic power values of the test power spectral characteristic differ from the corresponding acoustic power value of the reference power spectral characteristic by less than any of: 10 dB, 9 dB, 8 dB, 7 dB, 6 dB, 5 dB, 4 dB, 3 dB, 2 dB, 1.8 dB, 1.5 dB, 1.3 dB, 1 dB, 0.8 dB, 0.5 dB, and 0.3 dB. Accordingly, when docked, the electronic device 200 affects the sound produced by the dock 300. However, the effect is less than a threshold power value for each of the measured frequency bins.

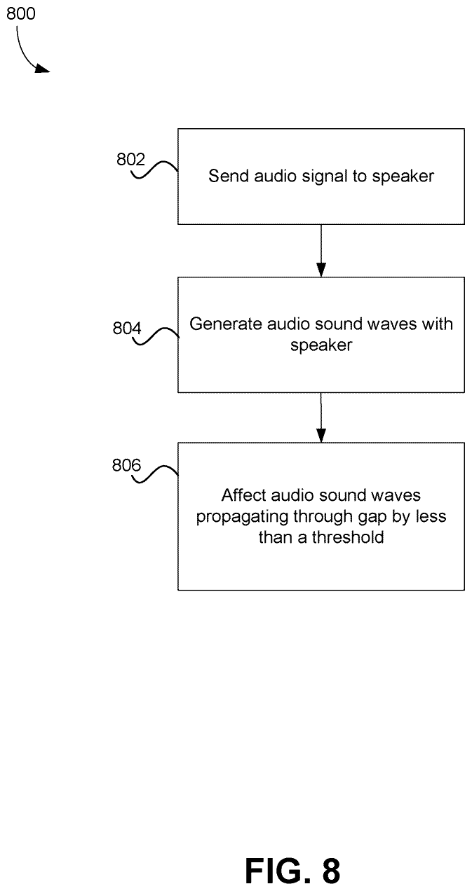

FIG. 8 illustrates a flowchart of a method 800 of operating a dock having an electronic device magnetically docked therewith, according to some implementations of the present disclosure. The method may be performed by, for example, dock 300 having electronic device 200 docked therewith, for example as illustrated in any or all of FIGS. 5-7.

At 802, an electronic signal is provided to a speaker of a dock. The electronic signal may be generated based on data of an audio file. In some embodiments, the audio file is stored on the electronic device.

In response to the electronic signal, at 804, the speaker generates audio compression waves corresponding with the data of the audio file.

At 808, the audio compression waves propagate from the dock and pass the electronic device. The electronic device affects the sound produced by the dock by less than a threshold power value for each of a plurality of frequency bins. For example, in some embodiments, acoustic power values of the sound is changed by less than any of: 10 dB, 9 dB, 8 dB, 7 dB, 6 dB, 5 dB, 4 dB, 3 dB, 2 dB, 1.8 dB, 1.5 dB, 1.3 dB, 1 dB, 0.8 dB, 0.5 dB, and 0.3 dB. Accordingly, when docked, the electronic device minimally affects the sound produced by the dock.

A foot of a dock, such as dock 300, may have an outward facing portion configured to engage a support surface on which the dock is placed. In some embodiments, the outward facing portion of the foot is planar or substantially planar.

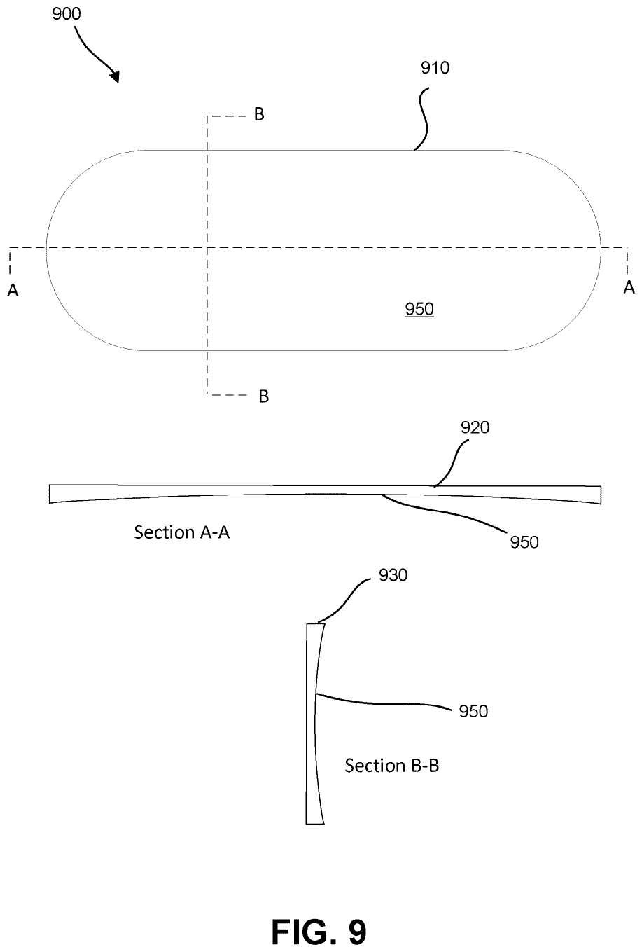

FIG. 9 illustrates a schematic plan view 910 and schematic cross-section views 920 and 930 of a foot 900 of a dock having an outward facing portion 950 which is nonplanar, according to some implementations of the present disclosure. At least partly because of the structure of the foot 900, a static friction between the foot and a supporting surface holding the dock is sufficient to prevent the dock from sliding or moving along the supporting surface, for example, when a speaker of the dock is generating sound. Because of the sound waves generated by the dock, the dock experiences vibrations. In addition, when the generated sound is at a resonant frequency of the dock, the vibrations may have particularly a high energy. In some circumstances, the vibrations, were it not for the foot 900, would cause the dock to move or slide along the supporting surface. This problem is particularly significant if the supporting surface is not level.

As illustrated in cross-sections 920 and 930, the outward facing portion 950 is concave. Accordingly, when the dock is placed on a supporting surface, outward facing portion 950 of foot 900 engages the supporting surface around the perimeter of foot 900. In some embodiments, outward facing portion 950 of foot 900 does not engage the supporting surface in a central portion of outward facing portion 950.

In some embodiments, the perimeter portions of foot 900 conformably engage the supporting surface. For example, foot 900 may be formed with an elastomeric material, which conforms such that a perimeter portion of foot 900 engages the supporting surface. In some embodiments, the perimeter portion of foot 900 engaging the supporting surface extends from the perimeter by a distance less than any of: 10 mm, 9 mm, 8 mm, 7 mm, 6 mm, 5 mm, 4 mm, 3 mm, 2 mm, and 1 mm. In some embodiments, the perimeter portion of foot 900 engaging the supporting surface extends from the perimeter by a distance which is any of: less than 10 mm and greater than 8 mm, less than 9 mm and greater than 7 mm, less than 8 mm and greater than 6 mm, less than 7 mm and greater than 5 mm, less than 6 mm and greater than 4 mm, less than 5 mm and greater than 4 mm, less than 4 mm and greater than 3 mm, less than 3 mm and greater than 2 mm, less than 2 mm and greater than 1 mm, less than 1 mm and greater than 0.5 mm.

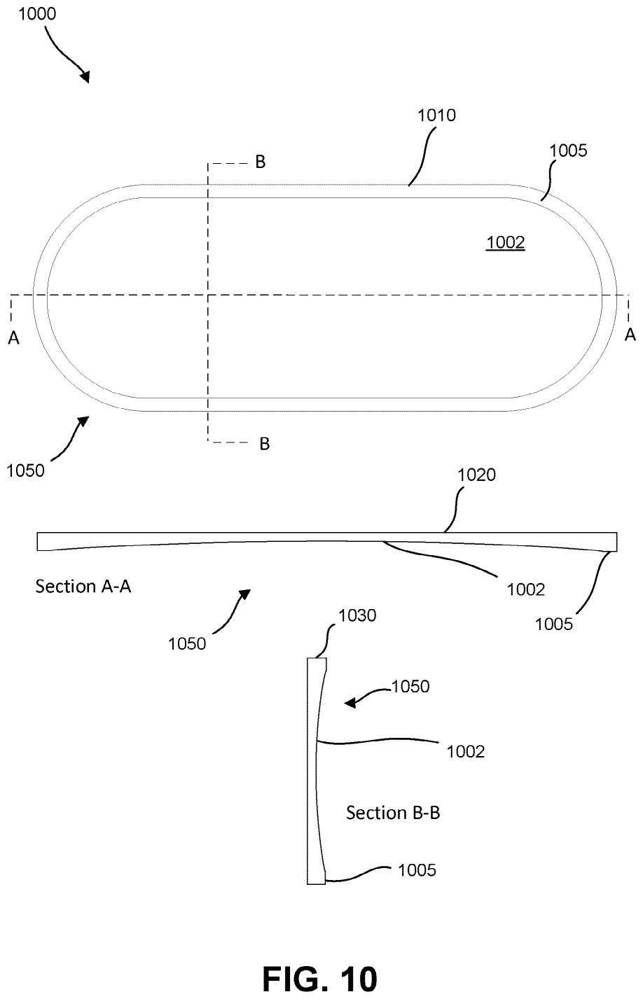

FIG. 10 illustrates a schematic plan view 1010 and schematic cross-section views 1020 and 1030 of a foot 1000 of a dock having an outward facing portion 1050 which is nonplanar, according to some implementations of the present disclosure. At least partly because of the structure of the foot 900, a static friction between the foot and a supporting surface holding the dock is sufficient to prevent the dock from sliding or moving along the supporting surface, for example, when a speaker of the dock is generating sound. Because of the sound waves generated by the dock, the dock experiences vibrations. In addition, when the generated sound is at a resonant frequency of the dock, the vibrations may have particularly a high energy. In some circumstances, the vibrations, were it not for the foot 900, would cause the dock to move or slide along the supporting surface. This problem is particularly significant if the supporting surface is not level.

As illustrated in cross-sections 1020 and 1030, the outward facing portion 1050 has a concave central area 1002 and a planar perimeter area 1005. Accordingly, when the dock is placed on a supporting surface, outward facing portion 1050 of foot 1000 engages the supporting surface around the perimeter area 1005 of foot 1000, and does not engage the supporting surface in the concave central area 1002.

In some embodiments, the perimeter area 1005 of foot 1000 extends from the perimeter by a distance less than any of: 10 mm, 9 mm, 8 mm, 7 mm, 6 mm, 5 mm, 4 mm, 3 mm, 2 mm, and 1 mm. In some embodiments, the perimeter area 1005 of foot 1000 extends from the perimeter by a distance which is any of: less than 10 mm and greater than 8 mm, less than 9 mm and greater than 7 mm, less than 8 mm and greater than 6 mm, less than 7 mm and greater than 5 mm, less than 6 mm and greater than 4 mm, less than 5 mm and greater than 4 mm, less than 4 mm and greater than 3 mm, less than 3 mm and greater than 2 mm, less than 2 mm and greater than 1 mm, less than 1 mm and greater than 0.5 mm.

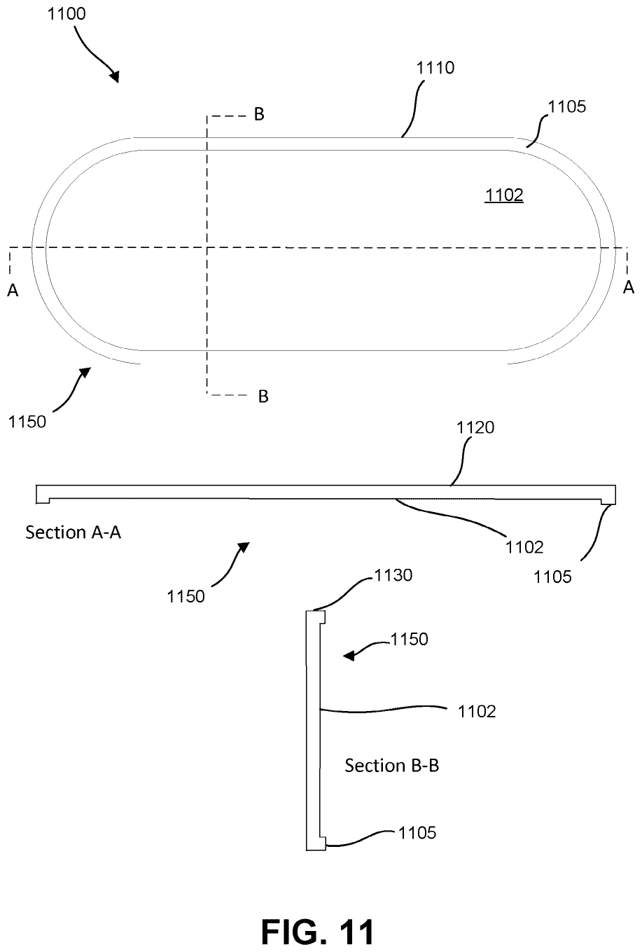

FIG. 11 illustrates a schematic plan view 1110 and schematic cross-section views 1120 and 1130 of a foot 1100 of a dock having an outward facing portion 1150 which is nonplanar, according to some implementations of the present disclosure. At least partly because of the structure of the foot 900, a static friction between the foot and a supporting surface holding the dock is sufficient to prevent the dock from sliding or moving along the supporting surface, for example, when a speaker of the dock is generating sound. Because of the sound waves generated by the dock, the dock experiences vibrations. In addition, when the generated sound is at a resonant frequency of the dock, the vibrations may have particularly a high energy. In some circumstances, the vibrations, were it not for the foot 900, would cause the dock to move or slide along the supporting surface. This problem is particularly significant if the supporting surface is not level.

As illustrated in cross-sections 1120 and 1130, the outward facing portion 1150 has a nonplanar central area 1102 and a planar perimeter area 1105. Accordingly, when the dock is placed on a supporting surface, outward facing portion 1150 of foot 1100 engages the supporting surface around the perimeter area 1105 of foot 1100, and does not engage the supporting surface in the planar central area 1102.

In some embodiments, the perimeter area 1105 of foot 1100 extends from the perimeter by a distance less than any of: 10 mm, 9 mm, 8 mm, 7 mm, 6 mm, 5 mm, 4 mm, 3 mm, 2 mm, and 1 mm. In some embodiments, the perimeter area 1105 of foot 1100 extends from the perimeter by a distance which is any of: less than 10 mm and greater than 8 mm, less than 9 mm and greater than 7 mm, less than 8 mm and greater than 6 mm, less than 7 mm and greater than 5 mm, less than 6 mm and greater than 4 mm, less than 5 mm and greater than 4 mm, less than 4 mm and greater than 3 mm, less than 3 mm and greater than 2 mm, less than 2 mm and greater than 1 mm, less than 1 mm and greater than 0.5 mm.

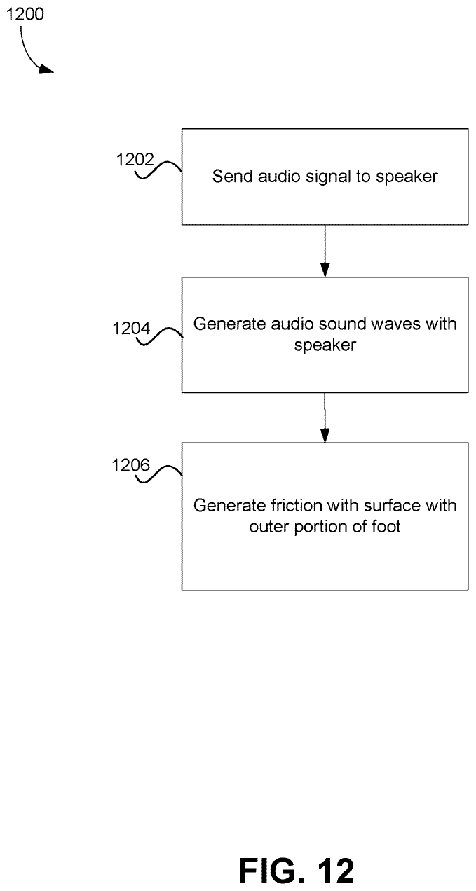

FIG. 12 illustrates a flowchart of a method 1200 of operating a dock, according to some implementations of the present disclosure. The method may be performed by, for example, dock 300 having a foot, for example as illustrated in any of FIGS. 9-11. The dock may either have an electronic device, such as electronic device 200 docked therewith or not have an electronic device docked therewith.

At 1202, an electronic signal is provided to a speaker of a dock positioned on a supporting surface such that an outer portion of the foot of the dock engages the supporting surface. The electronic signal may be generated based on data of an audio file. In some embodiments, the audio file is stored on the electronic device.

In response to the electronic signal, at 1204, the speaker generates audio compression waves corresponding with the data of the audio file.

At 1206, the outer portion of the foot frictionally engages the supporting surface such that the dock does not move with respect to the supporting service despite the operation of the speaker. In some embodiments, the frictional engagement of the foot with the supporting service causes the friction force between the foot and the supporting surface to be any of: greater than 2 ounces and less than 4 ounces, greater than 3 ounces and less than 5 ounces, greater than 4 ounces and less than 6 ounces, greater than 5 ounces and less than 7 ounces, greater than 6 ounces and less than 8 ounces, greater than 7 ounces and less than 9 ounces, greater than 8 ounces and less than 10 ounces, greater than 9 ounces and less than 11 ounces, greater than 10 ounces and less than 12 ounces, greater than 12 ounces and less than 15 ounces, greater than 14 ounces and less than 17 ounces, greater than 16 ounces and less than 20 ounces, and greater than 18 ounces and less than 24 ounces. In some embodiments. the coefficient of static friction between the foot and the supporting service is any of: greater than 1 ounces/pound and less than 3 ounces/pound, greater than 2 ounces/pound and less than 4 ounces/pound, greater than 3 ounces/pound and less than 5 ounces/pound, greater than 4 ounces/pound and less than 6 ounces/pound, greater than 5 ounces/pound and less than 7 ounces/pound, greater than 6 ounces/pound and less than 8 ounces/pound, greater than 7 ounces/pound and less than 9 ounces/pound, greater than 8 ounces/pound and less than 10 ounces/pound, greater than 9 ounces/pound and less than 11 ounces/pound, greater than 10 ounces/pound and less than 12 ounces/pound, greater than 12 ounces/pound and less than 15 ounces/pound, greater than 14 ounces/pound and less than 17 ounces/pound, greater than 16 ounces/pound and less than 20 ounces/pound, and greater than 18 ounces/pound and less than 24 ounces/pound. In some embodiments, the frictional engagement of the foot with the supporting service prevents movement of the dock despite the speaker generating an audio signal having power measured at any of: between 10 dB and 20 dB, between 15 dB and 25 dB, between 20 dB and 30 dB, between 25 dB and 35 dB, between 30 dB and 40 dB, between 35 dB and 45 dB, between 45 dB and 55 dB, between 50 dB and 60 dB, between 55 dB and 65 dB, between 60 dB and 70 dB, between 65 dB and 70 dB, between 70 dB and 80 dB, and between 75 dB and 85 dB, measured at a distance of 1 M from the dock, and the supporting surface being tilted from horizontal by 1.5 degrees.

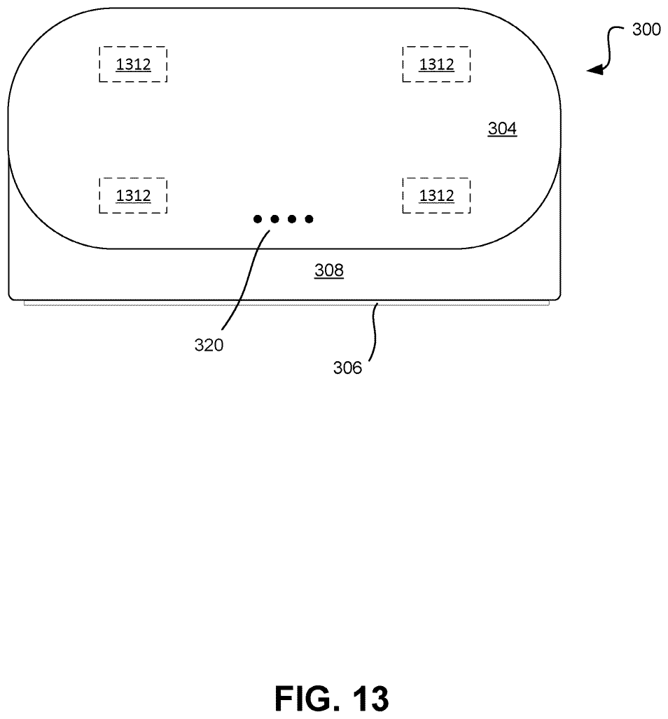

FIG. 13 illustrates a schematic front view of dock 300, according to some embodiments. Dock 300 may include a mating system, such as that described in more detail elsewhere herein. For example, dock 300 may have features similar or identical to those of dock 104 described above.

The mating system of dock 300 may include a magnet system and one or more magnetic field sensors, where the magnetic field sensors are located, for example, within dock 300 at one or more positions corresponding with optional placement locations 1312 on mating face 304. In some embodiments, magnetic field sensors are located at only two of the optional placement locations 1312. For example, magnetic field sensors may be located at the two lower optional placement locations 1312 according to the orientation of the figure, and not located at the two upper optional placement locations 1312 according to the orientation of the figure. The in some embodiments, only two magnetic field sensors are used and are located in opposite corners of the optional placement locations 1312. Other numbers of magnetic sensors and other configurations of the magnetic sensors may be used.

The magnet system may include one or more magnets arranged to align with and magnetically couple with corresponding one or more magnets of a magnet system of an electronic device docked with dock 300 such that a mating face of the electronic device is held against mating face 304 of dock 300 by the magnetic fields of the magnet system of dock 300 and the magnet system of the electronic device. The magnets of dock 300 may be located at any position. Accordingly, the number and location(s) of magnets are not limited, and the number and location(s) of the magnetic field sensors are not limited. In some embodiments, the one or more magnetic field sensors include magnets which magnetically couple with corresponding one or more magnets of a magnet system of an electronic device docked with dock 300.

The magnetic field sensors of dock 300 may include, for example, one or more magnetic field sensors, one or more magnetometers, one or more Hall effect sensors, and/or one or more other types of sensors configured to sense the presence of a magnet or a magnetic field. The magnetic field sensors may be configured to generate a signal indicative of proximity to a magnet.

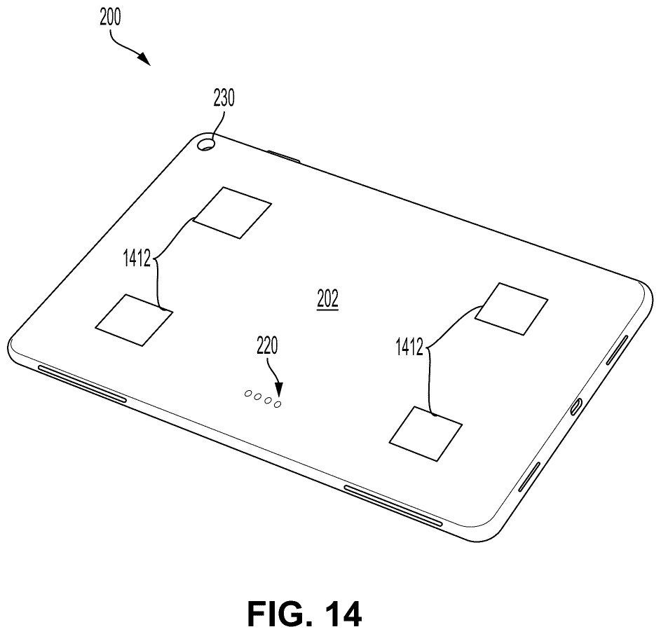

FIG. 14 illustrates an embodiment of an electronic device 200 that is configured to dock with a dock using an internal magnet system. The magnet system of electronic device 200 may include one or more magnets positioned, for example, within the electronic device 200 behind rear face 202, at positions corresponding with optional placement locations 1412 on mating surface 202, and corresponding with optional placement locations 1212 for the magnetic field sensors of dock 300. Device 200 includes multiple conductive electrical contacts 220 (e.g., metallic pads) that are used to transfer data with and/or obtain power from a dock when the electronic device 200 is in a docked position. Other components, such as camera 230, may be present on or accessible through rear face 202.

The magnet system may also include one or more magnets arranged to align with and magnetically couple with corresponding one or more magnets of a magnet system of dock 300 such that mating face 202 of the electronic device 200 is held against mating face 304 of dock 300 by the magnetic fields of the magnet system of dock 300 and the magnet system of the electronic device 200. The magnets of electronic device 200 may be located at any position. Accordingly, the number and location(s) of magnets are not limited, and the number and location(s) of the magnetic field sensors are not limited. In some embodiments, the one or more magnetic field sensors include magnets which magnetically couple with corresponding one or more magnets of a magnet system of dock 300.

The magnetic field sensors of electronic device 200, if any, may include, for example, one or more magnetic field sensors, one or more magnetometers, one or more Hall effect sensors, and/or one or more other types of sensors configured to sense the presence of a magnet or a magnetic field. The magnetic field sensors may be configured to generate a signal indicative of proximity to a magnet.

In some embodiments, the magnet system of either or both of the dock 300 and the electronic device 200 includes one or more magnet modules which are configured to receive one or more control signals. In response to control signals, generated, for example, by a processing system, each of the magnet modules is configured to generate a magnetic field corresponding with the received control signal. For example, control signals may cause the magnetic field of the magnet modules to at least one of increase, decrease, become substantially zero, and change north/south polarity. Accordingly, the control signals may cause the attractive force between an electronic device and the dock 300 to at least one of increase, decrease, become substantially zero, and become negative so that the force between the electronic device and the dock 300 is repulsive.

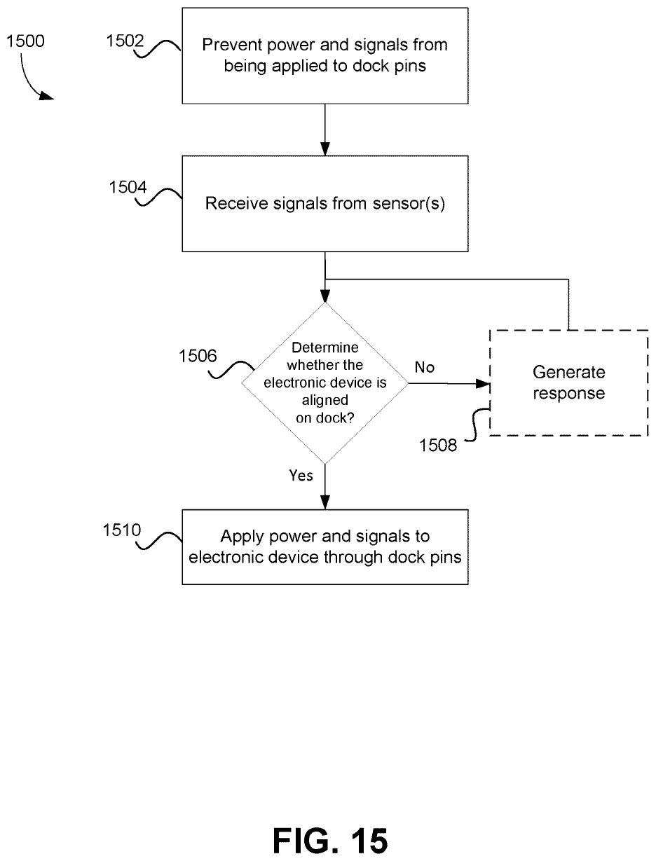

FIG. 15 illustrates a flowchart of a method 1500 of operating a dock having an electronic device magnetically docked with the dock, according to some implementations of the present disclosure. The method 1500 may be performed by, for example, dock 300 having electronic device 200 docked therewith.

At 1502, a processing system of the dock causes electrical contacts of the electronic device to be electrically inactive. For example, the processing system may cause a ground potential to be applied to electrical contacts. In some embodiments, the processing system causes the electrical contacts to be in a high impedance state condition, a tri-state condition, or an open condition, as understood by those of skill in the art.

In some embodiments, the processing system of the dock causes the electrical contacts to be electrically inactive in response to determining that the electronic device is not docked with the dock. For example, one or more sensors of either or both of the dock and the electronic device may generate or initiate signals corresponding with the undocked condition, and the processing system may, based on the generated signals, determine that the electronic device is not docked with the dock. For example, as discussed elsewhere herein, the sensors may include magnetic sensors which generate signals corresponding with sensed low magnetic field, indicating that the magnetic sensors and corresponding magnets are separated by a distance greater than a particular minimum corresponding with an undocked condition. In embodiments, where sensors of the electronic device generate or initiate the signals, the signals may be communicated to the dock wirelessly. In some embodiments, the processing system of the dock causes electrical contacts to be electrically inactive in response to determining that the electronic device is not docked with the dock and after a predetermined delay.

At 1504, the processing system of the dock receives signals from sensors of either or both of the dock and the electronic device, where the signals correspond with either of 1) an undocked condition corresponding with the electrical device not being docked with the dock, and 2) a docked condition corresponding with the electrical device being docked with the dock. For example, as discussed elsewhere herein, the sensors may include magnetic sensors which generate signals corresponding with sensed low magnetic field, indicating that the magnetic sensors and corresponding magnets are separated by a distance greater than a particular minimum distance corresponding with an undocked condition, and which generate signals corresponding with sensed high magnetic field, indicating that the magnetic sensors and corresponding magnets are separated by a distance less than a particular maximum distance corresponding with a docked condition. In embodiments where sensors of the electronic device generate or initiate the signals, the signals may be communicated to the dock wirelessly.

At 1506, the processing system determines whether the electronic device is docked with the dock. For example, the processing system may receive signals indicating that each of a plurality of sensors is generating or has generated signals corresponding with the docked or with the undocked condition.

If the processing system determines that the electronic device is undocked, at 1508, the processing system responds by causing or continuing to cause the electrical contacts of the electronic device to be electrically inactive. In some embodiments, the processing system causes electrical contacts to be electrically inactive in response to determining that the electronic device is not docked with dock and after a predetermined delay.

In some embodiments, at 1508, the processing system responds by changing the magnetic state of one or more magnet modules of the dock. In some circumstances, changing the magnetic states of the magnet modules may cause the electronic device to move with respect to the dock, and the movement may cause the electronic device to properly align with the dock such that the electronic device becomes properly docked.

In some embodiments, at 1508, the processing system responds by generating an indication that the electronic device is not properly docked. For example. the processing system may cause a characteristic sound to be generated by the speaker of the dock. In some embodiments. the processing system may cause a characteristic light, pattern of lights, or sequence of light signals to be generated. In some embodiments, a synthesized speech message may be output by the dock indicating the misalignment.

In some embodiments, at 1508, the processing system responds by wirelessly transmitting a signal to the electronic device indicating that the electronic device is not properly docked. In response to receiving the transmitted signal, the electronic device may generate an indication that the electronic device is not properly docked for the user. For example, the electronic device may cause a characteristic sound to be generated by the speaker of the dock or of the electronic device. In some embodiments, the electronic device may cause a characteristic light, pattern of lights, or sequence of light signals to be generated by the dock or by the electronic device. In some embodiments, the electronic device may cause a message to be displayed indicating that the electronic device is not properly docked with the dock. In some embodiments, a synthesized speech message may be output by the tablet device indicating the misalignment.

In some embodiments, a message may be output via the dock and/or the electronic device indicative of correct or incorrect alignment. For example, if properly aligned, a message can be displayed or auditory signal can be output indicating that alignment is correct and/or the electronic device is charging. In some embodiments, method 1500 involves no additional steps beyond outputting some form of indication regarding alignment.

In some embodiments, the dock may have the ability to readjust the alignment of the electronic device without help from a user. For example, if multiple electropermanent magnets are present as part of the docking system, the dock may be able to flip the polarity of the electropermanent magnets to cause an adjustment to the alignment of the electronic device. Such an adjustment may be sufficient to maneuver the electronic device into a proper alignment.

If, at 1506, the processing system determines that the electronic device is properly docked and aligned, at 1510, the processing system may respond by causing the electrical contacts of the electronic device to be electrically active. For example, the processing system may activate communication with the dock via the electrical contacts and/or activate power to the electrical contacts such that the electronic device can be powered and/or charge its one or more batteries. In some embodiments, the processing system causes electrical contacts to be electrically active in response to determining that the electronic device is properly docked with dock and after a predetermined delay.

It should be noted that the methods, systems, and devices discussed above are intended merely to be examples. It must be stressed that various embodiments may omit, substitute, or add various procedures or components as appropriate. For instance, it should be appreciated that, in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner. Also, it should be emphasized that technology evolves and, thus, many of the elements are examples and should not be interpreted to limit the scope of the invention.

Specific details are given in the description to provide a thorough understanding of the embodiments. However, it will be understood by one of ordinary skill in the art that the embodiments may be practiced without these specific details. For example, well-known, processes, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing embodiments of the invention. Various changes may be made in the function and arrangement of elements without departing from the spirit and scope of the invention.

Also, it is noted that the embodiments may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of steps may be undertaken before, during, or after the above elements are considered.

1. An electronic device dock system, comprising:
an electronic device, comprising:
a device front face configured to display images,
a device rear face opposite the device front face and comprising one or more device conductive elements,
one or more device magnet elements; and
a dock, comprising:
a dock front face comprising one or more dock conductive elements,
one or more dock magnet elements configured to magnetically couple with the device magnet elements, the device rear face of the electronic device being held against the dock front face at least partly by an attractive force generated by the dock magnet elements and the device magnet elements as a result of the device magnet elements being aligned with the dock magnet elements,
wherein the dock conductive elements electrically contact the device conductive elements as a result of the device magnet elements being aligned with the dock magnet elements, and
a processing system configured to selectively provide communication signals and power to the dock conductive elements; and
one or more magnetic field sensors configured to generate a sense signal,
wherein the processing system of the dock is configured to:
determine a device state based on the sense signal received from the one or more magnetic field sensors; and
apply at least one of power and a communication signal to the electronic device through the dock conductive elements based on the device state.

2. The electronic device dock system of claim 1, wherein the dock comprises the one or more magnetic field sensors.

3. The electronic device dock system of claim 2, wherein the device magnet elements of the electronic device are positioned on the electronic device so as to align with the magnetic field sensors on the dock when the electronic device is docked with the dock.

4. The electronic device dock system of claim 1, wherein the one or more magnetic field sensors comprise Hall-effect sensors.

5. The electronic device dock system of claim 1, wherein the processing system of the dock is configured cause the dock conductive elements to be electrically inactive as a result of the device state corresponding with the dock magnet elements not being aligned with the device magnet elements.

6. The electronic device dock system of claim 1, wherein the processing system of the dock is configured to generate an indication that the electronic device is not properly docked as a result of the device state corresponding with the dock magnet elements not being aligned with the device magnet elements.

7. The electronic device dock system of claim 1, wherein the one or more magnetic field sensors comprise exactly two sensors.

8. The electronic device dock system of claim 1, wherein the one or more magnetic field sensors comprise more than two sensors.

9. An electronic device dock system, comprising:
a dock, comprising:
a dock front face;
one or more dock magnet elements;
a speaker configured to generate sound having a power at each of a plurality of frequency bins, and
a foot; and
an electronic device, comprising:
a device front face configured to display images,
a device rear face opposite the device front face, and
one or more device magnet elements configured to align with the dock magnet elements, the device rear face being held against the dock front face at least partly by an attractive force generated by the dock magnet elements and the device magnet elements,
wherein, with the electronic device docked with the dock, the speaker is configured to generate docked sound, wherein the docked sound has a docked sound power at a distance of 30 cm from the speaker at each of the plurality of frequency bins, and wherein the docked sound is generated based on data of an audio file,
wherein, with the electronic device undocked, the speaker is configured to generate undocked sound having an undocked sound power at a distance of 30 cm from the speaker at each of the plurality of frequency bins, and wherein the undocked sound is generate based on the data of the audio file,
wherein the docked sound power at each particular frequency bin is less than 4 dB different from the undocked sound power at the particular frequency bin.

10. The electronic device dock system of claim 9, wherein the foot defines a foot plane, and wherein a portion of the electronic device nearest the foot plane is less than 30 mm from the foot plane.

11. The electronic device dock system of claim 10, wherein the portion of the electronic device nearest the foot plane is less than 30 mm from the dock.

12. The electronic device dock system of claim 9, wherein an occlusion plane contacts the electronic device and the dock such that the dock is occluded by electronic device from points of view which are between the occlusion plane and the electronic device on the device front face side of the electronic device.

13. The electronic device dock system of claim 12, wherein the foot defines a foot plane, and wherein the occlusion plane intersects the foot plane with an angle which is less than 50 degrees.

14. The electronic device dock system of claim 9, wherein the foot defines a foot plane, and wherein the speaker of the dock defines a speaker plane, and wherein the speaker plane intersects the foot plane with an angle which is less than 90 degrees.

15. A dock for an electronic device dock system, the dock comprising:
a housing;
a speaker within the housing;
a foot fixed to the housing, wherein the foot comprises an outward facing portion comprising:
a first portion defining a foot plane, and
a second portion which is between the foot plane and the housing;
a front element having a mating surface attached to the housing; and
one or more dock magnet elements configured to generate an attractive force to hold an electronic device against the mating surface.

16. The dock of claim 15, wherein the first portion of the foot is spaced apart from a first portion of the housing closest to the first portion of the foot by a first distance, wherein the second portion of the foot is spaced apart from a second portion of the housing closest to the second portion of the foot by a second distance, and wherein the first distance is greater than the second distance.

17. The dock of claim 15, wherein the outward facing portion is nonplanar.

18. The dock of claim 15, wherein the outward facing portion is concave.

19. The dock of claim 15, wherein the outward facing portion comprises a concave portion and a planar portion.

20. The dock of claim 15, wherein the outward facing portion is nonplanar and comprises first and second planar sections.
